(19) United States
(12) Patent Application Publication
(10) Pub. No.: US 2009/0045480 A1
(43) Pub. Date: Feb. 19, 2009

(54) SEMICONDUCTOR INTEGRATED CIRCUIT

(76) Inventors: Hiroki Matsunaga, Osaka (JP); Naoki Hishikawa, Kyoto (JP); Akihiro Maejima, Osaka (JP); Jinsaku Kaneda, Osaka (JP); Hiroshi Ando, Osaka (JP)

Correspondence Address: MCDERMOTT WILL & EMERY LLP, 600 13TH STREET, NW, WASHINGTON, DC, 20005-3096, US

(21) Appl. No.: 12/094,499

(22) PCT Filed: Nov. 7, 2006
(86) PCT No.: PCT/JP2006/322177

§ 371 Date: May 21, 2008

(30) Foreign Application Priority Data
Mar. 2, 2006 (JP) 2006-056663

(51) Int. Cl. H01L 27/02

(52) U.S. Cl. 257/491; 257/E27.009

(57) ABSTRACT

A semiconductor integrated circuit includes a plurality of circuit cells on a semiconductor chip. The plurality of circuit cells are formed along a first chip side of the semiconductor chip. Each of the plurality of circuit cells has a pad. The semiconductor integrated circuit further includes a high voltage potential interconnect formed over the plurality of circuit cells. The high voltage potential interconnect has a width expanding in a length direction from a center portion to end portions of the high voltage potential interconnect.

### TECHNICAL FIELD

The present invention relates to a semiconductor integrated circuit. Specifically, the present invention relates to a layout of a multi-channel semiconductor integrated circuit for driving a capacitive load such as a plasma display.

### BACKGROUND ART

Generally, a MOS output circuit, an IGBT output circuit, a high-sideless MOS circuit, or a high-sideless IGBT output circuit has been known as an output circuit used for a multi-channel semiconductor integrated circuit. Moreover, a multi-channel semiconductor integrated circuit including cells of such output circuits as standard cells has a layout, for example, in which a low breakdown voltage control portion for controlling output timing by an input control circuit or the like is arranged in the center of a semiconductor chip, standard cell groups composed of a plurality of standard cells formed along chip sides of the semiconductor chip are arranged to face each other with the low breakdown voltage control portion interposed therebetween, and reference potential interconnects having a constant width and high voltage potential interconnects having a constant width are arranged over the standard cell groups, wherein the reference potential interconnects are connected to reference potential pads arranged on both ends of the standard cell groups, and the high voltage potential interconnects are connected to high voltage power source pads arranged on both the ends of the standard cell groups (with regard to this layout, see Patent Document 1, for example).

Patent Document 1: Japanese Laid-Open Patent Publication No. 60-46041

### DISCLOSURE OF INVENTION

### Problems to be Solved by the Invention

In the conventional layout of the multi-channel semiconductor integrated circuit, the reference potential interconnects and the high voltage potential interconnects have a constant width. Therefore, outputs arranged in the center of the semiconductor chip and outputs arranged in end portions of the semiconductor chip are different in interconnect resistance. This results in a problem that a difference in voltage drop may vary an ON resistance characteristic and ESD tolerance of outputs.

In view of the above mentioned problems, an object of the present invention is to provide a semiconductor integrated circuit having a layout allowing output circuits to have uniform characteristics.

### Means for Solving the Problems

To achieve the above-mentioned object, a semiconductor integrated circuit according to a first aspect of the present invention includes a plurality of circuit cells on a semiconductor chip, the plurality of circuit cells being formed along a first chip side of the semiconductor chip and each of the plurality of circuit cells having a pad, the semiconductor integrated circuit including a high voltage potential interconnect formed over the plurality of circuit cells, wherein the high voltage potential interconnect has a width expanding in a length direction from a center portion to an end portion of the high voltage potential interconnect.

In the semiconductor integrated circuit according to the first aspect of the present invention, each of the circuit cells includes: a high breakdown voltage driver; a pre-driver for driving the high breakdown voltage driver; and the pad.

In a first configuration (for example, in the case of an output circuit including a MOS driver) of the semiconductor integrated circuit according to the first aspect of the present invention, the high breakdown voltage driver includes a high-side transistor and a low-side transistor, and the pre-driver includes a level shift circuit for driving the high-side transistor.

In the first configuration of the first aspect, it is preferable that the pre-driver, the pad, the high-side transistor, the level shift circuit, and the low-side transistor are arranged in alignment with each other along a straight line, wherein at least the high-side transistor and the low-side transistor are arranged to face each other with the pad interposed therebetween.

The first configuration of the first aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The first configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and first reference potential interconnects arranged over the low-side transistors of the first circuit cell alignment and the second circuit cell alignment, the first reference potential interconnects being electrically connected to the second power source pads, wherein the high voltage potential interconnects are arranged over the high-side transistors of the first circuit cell alignment and the second circuit cell alignment and are electrically connected to the first power source pads.

The first configuration of the first aspect further includes a second reference potential interconnect surrounding a region for the control portion arranged in the center of the semiconductor chip.

In the first configuration of the first aspect, each of the level shift circuit and the pre-driver is designed to have a cell width smaller than or equal to that of the low-side transistor.

In a second configuration (for example, in the case of an output circuit including an IGBT output circuit) of the semiconductor integrated circuit according to the first aspect of the present invention, the high breakdown voltage driver includes: a high-side transistor; a high-side regenerative diode; a low-side transistor; and a low-side regenerative diode.

In the second configuration of the first aspect, it is preferable that the pre-driver, the pad, the high-side transistor, the level shift circuit, the high-side regenerative diode, the low-side transistor, and the low-side regenerative diode are arranged in alignment with each other along a straight line, wherein at least the high-side regenerative diode and the low-side regenerative diode are arranged to face each other with the pad interposed therebetween.

The second configuration of the first aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The second configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and first reference potential interconnects arranged over the low-side transistors of the first circuit cell alignment and the second circuit cell alignment, the first reference potential interconnects being electrically connected to the second power source pads, wherein the high voltage potential interconnects are arranged over the high-side regenerative diodes of the first circuit cell alignment and the second circuit cell alignment and are electrically connected to the first power source pads.

The second configuration of the first aspect further includes a second reference potential interconnect surrounding a region for the control portion arranged in the center of the semiconductor chip.

In the second configuration of the first aspect, each of the level shift circuit and the pre-driver is designed to have a cell width smaller than or equal to that of the low-side transistor.

In a third configuration (for example, in the case of an output circuit including a high-sideless MOS driver) of the semiconductor integrated circuit according to the first aspect of the present invention, the high breakdown voltage driver includes: an ESD protection device; and a low-side transistor.

In the third configuration of the first aspect, it is preferable that the pre-driver, the pad, the ESD protection device, and the low-side transistor are arranged in alignment with each other along a straight line, wherein at least the ESD protection device and the low-side transistor are arranged to face each other with the pad interposed therebetween.

The third configuration of the first aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The third configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and first reference potential interconnects arranged over the low-side transistors of the first circuit cell alignment and the second circuit cell alignment, the first reference potential interconnects being electrically connected to the second power source pads, wherein the high voltage potential interconnects are arranged over the ESD protection devices of the first circuit cell alignment and the second circuit cell alignment and are electrically connected to the first power source pads.

The third configuration of the first aspect further includes a second reference potential interconnect surrounding a region for the control portion arranged in the center of the semiconductor chip.

In the third configuration of the first aspect, the pre-driver is designed to have a cell width smaller than or equal to that of the low-side transistor.

In a fourth configuration (for example, in the case of an output circuit including a high-sideless IGBT output circuit) of the semiconductor integrated circuit according to the first aspect of the present invention, the high breakdown voltage driver includes: an ESD protection device; a low-side regenerative diode; and a low-side transistor.

In the fourth configuration of the first aspect, it is preferable that the pre-driver, the pad, the ESD protection device, the low-side regenerative diode, and the low-side transistor are arranged in alignment with each other along a straight line, wherein at least the ESD protection device and the low-side regenerative diode are arranged to face each other with the pad interposed therebetween.

The fourth configuration of the first aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The fourth configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and first reference potential interconnects arranged over the low-side transistors of the first circuit cell alignment and the second circuit cell alignment, the first reference potential interconnects being electrically connected to the second power source pads, wherein the high voltage potential interconnects are arranged over the ESD protection devices of the first circuit cell alignment and the second circuit cell alignment and are electrically connected to the first power source pads.

The fourth configuration of the first aspect further includes a second reference potential interconnect surrounding a region for the control portion arranged in the center of the semiconductor chip.

In the fourth configuration of the first aspect, the pre-driver is designed to have a cell width smaller than or equal to that of the low-side transistor.

A semiconductor integrated circuit according to a second aspect of the present invention includes a plurality of circuit cells on a semiconductor chip, the plurality of circuit cells being formed along a first chip side of the semiconductor chip and each of the plurality of circuit cells having a pad, the semiconductor integrated circuit including a first reference potential interconnect formed over the plurality of circuit cells, wherein the first reference potential interconnect has a width expanding in a length direction from a center portion to an end portion of the first reference potential interconnect.

In the semiconductor integrated circuit according to the second aspect of the present invention, each of the circuit cells includes: a high breakdown voltage driver; a pre-driver for driving the high breakdown voltage driver; and the pad.

In a first configuration (for example, in the case of an output circuit including a MOS driver) of the semiconductor integrated circuit according to the second aspect of the present invention, the high breakdown voltage driver includes a high-side transistor and a low-side transistor, and the pre-driver includes a level shift circuit for driving the high-side transistor.

In the first configuration of the second aspect, it is preferable that the pre-driver, the pad, the high-side transistor, the level shift circuit, and the low-side transistor are arranged in alignment with each other along a straight line, wherein at least the high-side transistor and the low-side transistor are arranged to face each other with the pad interposed therebetween.

The first configuration of the second aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The first configuration of the second aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and high voltage potential interconnects arranged over the high-side transistors of the first circuit cell alignment and the second circuit cell alignment, the high voltage potential interconnects being electrically connected to the first power source pads, wherein the first reference potential interconnects are arranged over the low-side transistors of the first circuit cell alignment and the second circuit cell alignment and are electrically connected to the second power source pads.

The first configuration of the second aspect further includes a second reference potential interconnect surrounding a region for the control portion arranged in the center of the semiconductor chip.

In the first configuration of the second aspect, each of the level shift circuit and the pre-driver is designed to have a cell width smaller than or equal to that of the low-side transistor.

In a second configuration (for example, in the case of an output circuit including an IGBT output circuit) of the semiconductor integrated circuit according to the second aspect of the present invention, the high breakdown voltage driver includes: a high-side transistor; a high-side regenerative diode; a low-side transistor; and a low-side regenerative diode.

In the second configuration of the second aspect, it is preferable that the pre-driver, the pad, the high-side transistor, the level shift circuit, the high-side regenerative diode, the low-side transistor, and the low-side regenerative diode are arranged in alignment with each other along a straight line, wherein at least the high-side regenerative diode and the low-side regenerative diode are arranged to face each other with the pad interposed therebetween.

The second configuration of the second aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The second configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and high voltage potential interconnects arranged over the high-side regenerative diodes of the first circuit cell alignment and the second circuit cell alignment, the high voltage potential interconnects being electrically connected to the first power source pads, wherein the first reference potential interconnects are arranged over the low-side transistors of the first circuit cell alignment and the second circuit cell alignment and are electrically connected to the second power source pads.

The second configuration of the second aspect further includes a second reference potential interconnect surrounding a region for the control portion arranged in the center of the semiconductor chip.

In the second configuration of the second aspect, each of the level shift circuit and the pre-driver is designed to have a cell width smaller than or equal to that of the low-side transistor.

In a third configuration (for example, in the case of an output circuit including a high-sideless MOS driver) of the semiconductor integrated circuit according to the second aspect of the present invention, the high breakdown voltage driver includes: an ESD protection device; and a low-side transistor.

In the third configuration of the second aspect, it is preferable that the pre-driver, the pad, the ESD protection device, and the low-side transistor are arranged in alignment with each other along a straight line, wherein at least the ESD protection device and the low-side transistor are arranged to face each other with the pad interposed therebetween.

The third configuration of the second aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The third configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and high voltage potential interconnects arranged over the ESD protection devices of the first circuit cell alignment and the second circuit cell alignment, the high voltage potential interconnects being electrically connected to the first power source pads, wherein the first reference potential interconnects are arranged over the low-side transistors of the first circuit cell alignment and the second circuit cell alignment and are electrically connected to the second power source pads.

The third configuration of the second aspect further includes a second reference potential interconnect surrounding a region for the control portion arranged in the center of the semiconductor chip.

In the third configuration of the second aspect, the pre-driver is designed to have a cell width smaller than or equal to that of the low-side transistor.

In a fourth configuration (for example, in the case of an output circuit including a high-sideless IGBT output circuit) of the semiconductor integrated circuit according to the second aspect of the present invention, the high breakdown voltage driver includes: an ESD protection device; a low-side regenerative diode; and a low-side transistor.

In the fourth configuration of the second aspect, it is preferable that the pre-driver, the pad, the ESD protection device, the low-side regenerative diode, and the low-side transistor are arranged in alignment with each other along a straight line, wherein at least the ESD protection device and the low-side regenerative diode are arranged to face each other with the pad interposed therebetween.

The fourth configuration of the second aspect further includes: a control portion arranged in the center of the semiconductor chip; and a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

The fourth configuration of the first aspect further includes: first power source pads for a high voltage potential, the first power source pads being arranged on both ends of each of the first circuit cell alignment and the second circuit cell alignment; second power source pads for a reference potential, the second power source pads being arranged on both the ends of each of the first circuit cell alignment and the second circuit cell alignment; and high voltage potential interconnects arranged over the ESD protection devices of the first circuit cell alignment and the second circuit cell alignment, the high voltage potential interconnects being electrically connected to the first power source pads, wherein the first reference potential interconnects are arranged over the low-side transistors of the first circuit cell alignment and the second circuit cell alignment and are electrically connected to the second power source pads.

The fourth configuration of the second aspect further includes a second reference potential interconnect surrounding a region for the control portion arranged in the center of the semiconductor chip.

In the fourth configuration of the second aspect, the pre-driver is designed to have a cell width smaller than or equal to that of the low-side transistor.

### EFFECTS OF THE INVENTION

According to the present invention, since imbalance in interconnect impedance from a high voltage power source pad or a reference potential pad to respective circuit cells can be reduced in a multi-channel semiconductor integrated circuit, a variation in ON resistance characteristics and a variation in ESD tolerance can be suppressed, making characteristics of standard cells uniform.

### BRIEF DESCRIPTION OF DRAWINGS

FIG. 1 is a view showing an exemplary circuit configuration of an output circuit including a MOS driver having a pad according to Embodiment 1 of the present invention.

FIG. 2 is a view showing an exemplary circuit configuration of an output circuit including an IGBT output circuit having a pad according to Embodiment 2 of the present invention.

FIG. 3 is a view showing an exemplary circuit configuration of an output circuit including a high-sideless MOS driver having a pad according to Embodiment 3 of the present invention.

FIG. 4 is a view showing an exemplary circuit configuration of an output circuit including a high-sideless IGBT output circuit having a pad according to Embodiment 4 of the present invention.

FIG. 5 is a plan view showing a layout of a semiconductor integrated circuit according to Embodiment 1 of the present invention.

FIGS. 6A and 6B are enlarged plan views each showing an output circuit cell according to Embodiment 1 of the present invention.

FIG. 7 is a plan view showing a layout of a variation of the semiconductor integrated circuit according to Embodiment 1 of the present invention.

FIG. 8 is a plan view showing a layout of a semiconductor integrated circuit according to Embodiment 2 of the present invention.

FIGS. 9A and 9B are enlarged plan views each showing an output circuit cell according to Embodiment 2 of the present invention.

FIG. 10 is a plan view showing a layout of a variation of the semiconductor integrated circuit according to Embodiment 2 of the present invention.

FIG. 11 is a plan view showing a layout of a semiconductor integrated circuit according to Embodiment 3 of the present invention.

FIGS. 12A and 12B are enlarged plan views each showing an output circuit cell according to Embodiment 3 of the present invention.

FIG. 13 is a plan view showing a layout of a variation of the semiconductor integrated circuit according to Embodiment 3 of the present invention.

FIG. 14 is a plan view showing a layout of a semiconductor integrated circuit according to Embodiment 4 of the present invention.

FIGS. 15A and 15B are enlarged plan views each showing an output circuit cell according to Embodiment 4 of the present invention.

FIG. 16 is a plan view showing a layout of a variation of the semiconductor integrated circuit according to Embodiment 4 of the present invention.

### DESCRIPTION OF REFERENCE NUMERALS

1 semiconductor chip
2, 2b high voltage potential interconnect
3a, 3aA, 3aB, 3aC, 3aD, 3b reference potential interconnect
4 high voltage power source pad
5 reference potential pad
6 low breakdown voltage control portion
7 bus interconnect
8 pad
9 input control pad
10 high-side transistor
11 low-side transistor
12 level shift circuit
13 pre-driver
14 two-layer interconnect
15 one-layer interconnect
16A through 16D output circuit cell
19 drain region of high-side transistor
20 source region of high-side transistor
21 through hole
22 drain region of low-side transistor
23 source region of low-side transistor
24 input terminal
25a through 25d output circuit
26 back gate-drain parasitic diode
27 back gate-drain parasitic diode
28 high-side transistor
29 low-side transistor
30 high-side regenerative diode
31 low-side regenerative diode
32 gate protection diode
33 gate-off resistor
34 gate protection circuit
35 emitter region of high-side transistor
36 corrector region of high-side transistor
37 emitter region of low-side transistor
38 corrector region of low-side transistor
39 diode cathode region
40 diode anode region
41 contact
43 ESD protection device
44 pre-driver
45 MOS driver
46 IGBT output circuit
47 high-sideless MOS driver
48 high-sideless IGBT output circuit

### BEST MODE FOR CARRYING OUT THE INVENTION

Before describing Embodiments of the present invention, technical idea of the present invention in which Embodiments are comprehended will be described below.

Namely, the present invention is a semiconductor integrated circuit including a plurality of circuit cells on a semiconductor chip, the plurality of circuit cells being formed along a first chip side of the semiconductor chip and each of the plurality of circuit cells having a pad, the semiconductor integrated circuit including at least one of a high voltage potential interconnect and a reference potential interconnect which are formed over the plurality of circuit cells, wherein the at least one of the high voltage potential interconnect and the reference potential interconnect has a width expanding in a length direction from a center portion to end portions thereof.

Thus, the semiconductor integrated circuit of the present invention can reduce the imbalance in interconnect impedance from a high voltage power source pad or a reference potential pad to respective circuit cells, allowing a variation in ON resistance characteristics and a variation in ESD tolerance to be suppressed, which can make characteristics of the circuit cells uniform.

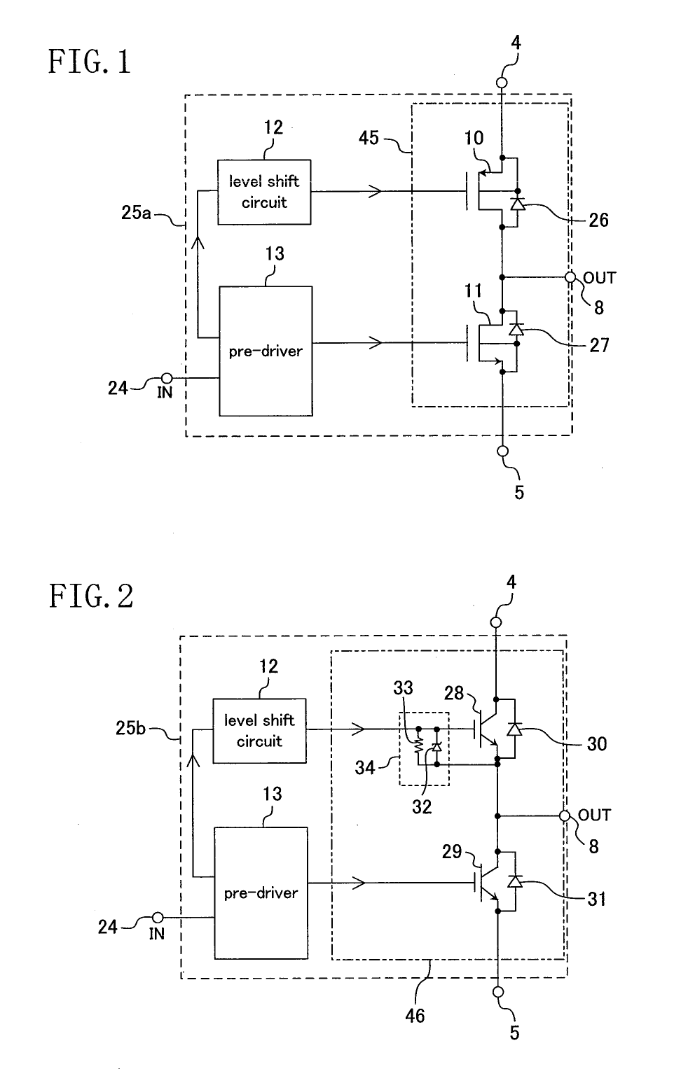

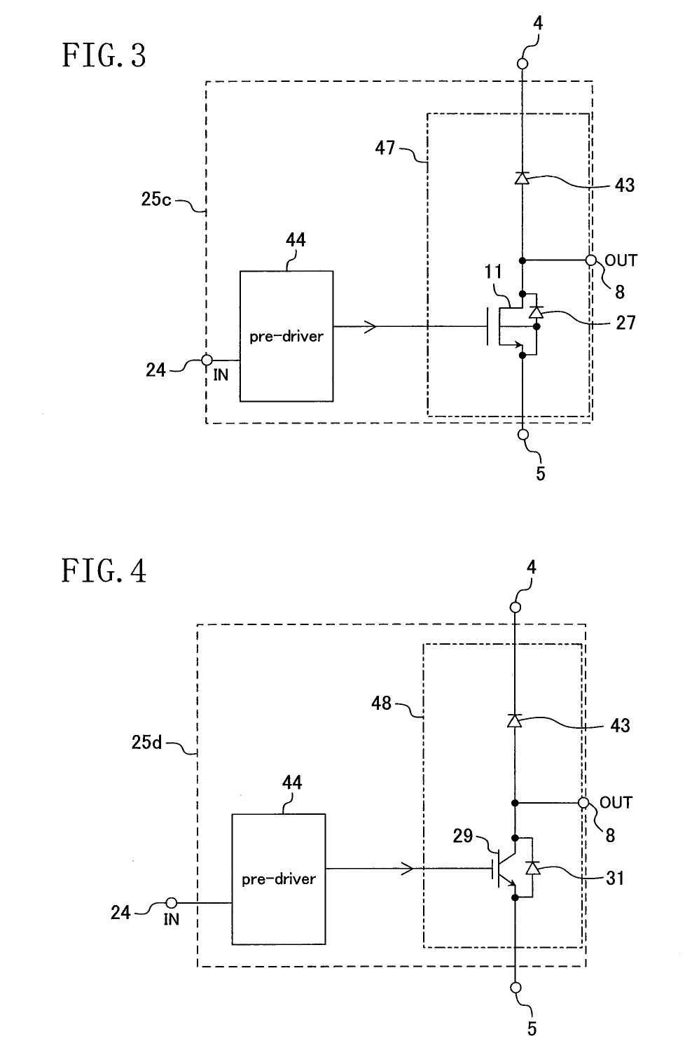

Each circuit cell of the semiconductor integrated circuit of the present invention includes a high breakdown voltage driver, a pre-driver for driving the high breakdown voltage driver, and a pad. Specifically, detailed descriptions will be given with reference to Embodiments. Examples of the circuit cell are an output circuit 25a including a MOS driver 45 of FIG. 1, an output circuit 25b including an IGBT output circuit 46 of FIG. 2, an output circuit 25c including a high-sideless MOS driver 47 of FIG. 3, and an output circuit 25d including a high-sideless IGBT output circuit 48 of FIG. 4.

Here, descriptions are given of exemplary basic circuit configurations of output circuits 25a through 25d of FIGS. 1 through 4.

The output circuit 25a of FIG. 1 includes a MOS driver 45, a level shift circuit 12, and a pre-driver 13. Here, the MOS driver 45 is composed of a high-side transistor 10, a back gate-drain parasitic diode 26 serving as a parasitic element of the high-side transistor 10, a low-side transistor 11, a back gate-drain parasitic diode 27 serving as a parasitic element of the low-side transistor 11, and a pad 8. Moreover, the high-side transistor 10 is connected to a high voltage power source pad 4. The low-side transistor 11 is connected to a reference potential pad 5. The pre-driver 13 is connected to an input terminal 24. Note that, the high-side transistor 10 is used for high level outputting, and the low-side transistor 11 is used for low level outputting.

The output circuit 25b of FIG. 2 includes an IGBT output circuit 46, a level shift circuit 12, and a pre-driver 13. The IGBT output circuit 46 is composed of a high-side transistor 28, a gate protection circuit 34 having a gate-off resistor 33 and a gate protection diode 32, a high-side regenerative diode 30, a low-side transistor 29, a low-side regenerative diode 31, and a pad 8. Moreover, the high-side transistor 28 is connected to a high voltage power source pad 4. The low-side transistor 29 is connected to a reference potential pad 5. The pre-driver 13 is connected to an input terminal 24.

The output circuit 25c of FIG. 3 includes a high-sideless MOS driver 47 and a pre-driver 44. The high-sideless MOS driver 47 is composed of a low-side transistor 11, a back gate-drain parasitic diode 27 serving as a parasitic element of the low-side transistor 11, an ESD protection device 43, and a pad 8. Moreover, one end of the low-side transistor 11 is connected to a high voltage power source pad 4. The other end of the low-side transistor 11 is connected to a reference potential pad 5. The pre-driver 44 is connected to an input terminal 24.

The output circuit 25d of FIG. 4 includes a high-sideless IGBT output circuit 48 and a pre-driver 44. The high-sideless IGBT output circuit 48 is composed of a low-side transistor 29, a low-side regenerative diode 31, an ESD protection device 43, a pad 8, a high voltage power source pad 4, and a reference potential pad 5. Moreover, one end of the low-side transistor 29 is connected to the high voltage power source pad 4. The other end of the low-side transistor 29 is connected to the reference potential pad 5. The pre-driver 44 is connected to an input terminal 24.

Embodiments of the present invention will be described below in reference to the drawings, wherein the above-mentioned output circuits of FIGS. 1 through 4 are used as examples.

### EMBODIMENT 1

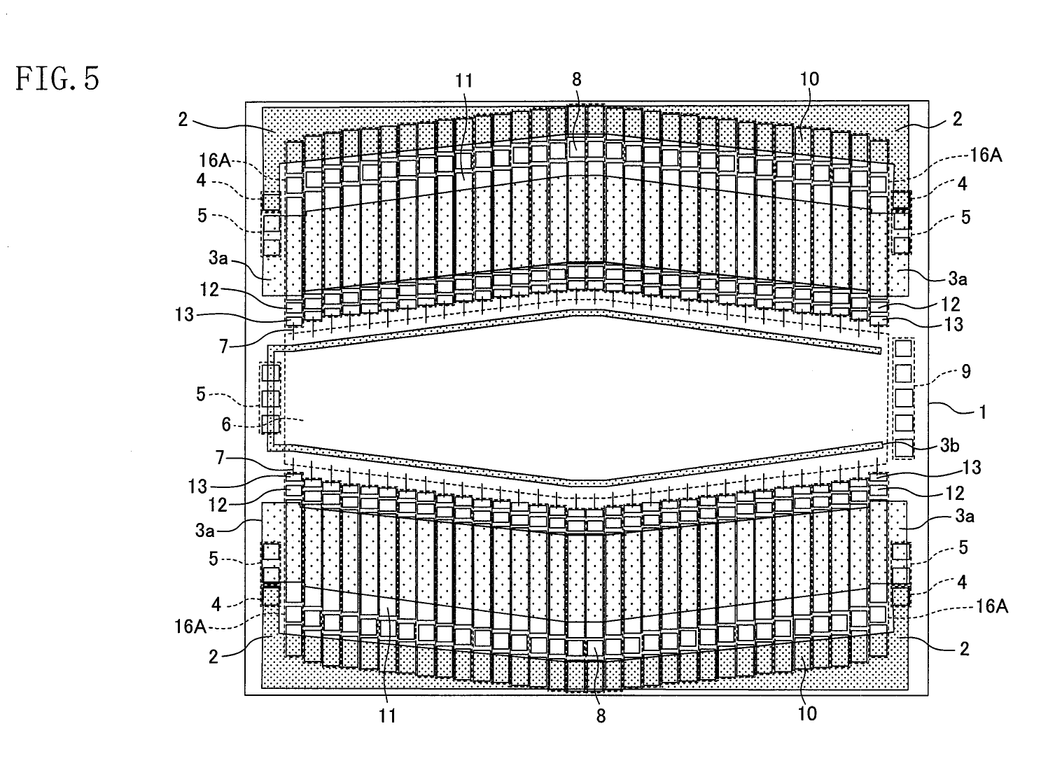

FIG. 5 is a plan view illustrating a layout of a multi-channel semiconductor integrated circuit of Embodiment 1 of the present invention. Specifically, descriptions are given taking a multi-channel semiconductor integrated circuit provided with output circuits 25a each including the MOS driver 45 of FIG. 1 mentioned above as an example.

As shown in FIG. 5, a low breakdown voltage control portion 6 is arranged in the center of a semiconductor chip 1. The low breakdown voltage control portion 6 controls output timing by an input control circuit or the like. Moreover, on the semiconductor chip 1, a plurality of output circuit cells 16A is arranged along chip sides to face each other with the low breakdown voltage control portion 6 interposed therebetween. Each of the plurality of circuit cells 16A has the configuration of the output circuit 25a of FIG. 1. The low breakdown voltage control portion 6 is connected to the output circuit cells 16A via bus interconnects 7. Moreover, high voltage power source pads 4 are arranged on both ends of the plurality of output circuit cells 16A, and reference potential pads 5 are arranged on both the ends of the plurality of output circuit cells 16A.

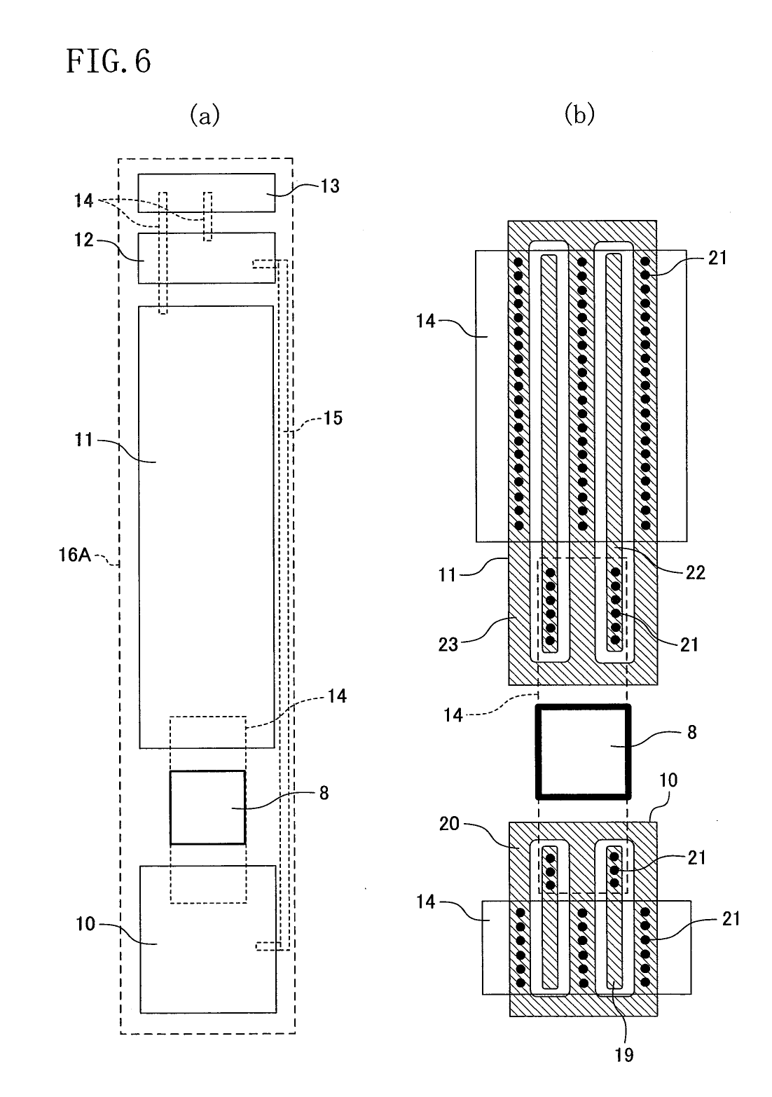

Each output circuit cell 16A is composed of the pad 8, the high-side transistor 10, the low-side transistor 11, the level shift circuit 12, and the pre-driver 13 which are arranged in alignment with each other along a straight line, wherein centering on the pad 8, the low-side transistor 11, the level shift circuit 12, and the pre-driver 13 are sequentially arranged on one side toward the low breakdown voltage control portion 6, and the high-side transistor 10 is arranged on the other side. It is to be noted that a timing control signal from the low breakdown voltage control portion 6 is transmitted to the pre-drivers 13 through the bus interconnects 7. Moreover, components in each output circuit cell 16A are connected via contacts 21 by a two-layer interconnect 14 or a one-layer interconnect 15 as shown in FIGS. 6A and 6B. In FIG. 6B, a drain region 19 of the high-side transistor 10, a source region 20 of the high-side transistor 10, a drain region 22 of the low-side transistor 11, and a source region 23 of the low-side transistor 11 are shown.

As mentioned above, the high-side transistor 10 including the back gate-drain parasitic diode 26 and the low-side transistor 11 including the back gate-drain parasitic diode 27 are arranged with the pad 8 interposed therebetween, the back gate-drain parasitic diode 26 and the back gate-drain parasitic diode 27 also serving as ESD protection devices in consideration of improving the ESD tolerance. Thus, the effect of ESD protection can be enhanced. Moreover, each of the level shift circuit 12 and the pre-driver 13 is designed to have a cell width smaller than or equal to that of the low-side transistor 11, where the low-side transistor 11 has the largest cell width, so that a high degree of integration can be realized.

Moreover, the plurality of output circuit cells 16A is arranged having a steplike shift in a direction apart from the chip sides with decreasing distance from a center portion to end portions of the chip sides of the semiconductor chip 1. That is, a layout is performed such that bonding wires (not shown) connecting the pads 8 to inner leads which are not shown are not in contact with each other. Therefore, enhancement of reliability as to assembly can be realized, and the integration degree of the semiconductor integrated circuit can be improved. It is to be noted that this layout of the plurality of output circuit cells 16A is not restrictive. Any layout, such as a layout in which the output circuit cells are stepwise shifted as mentioned above only in the vicinity of the end portions the chip sides of the semiconductor chip 1 (corners of the semiconductor chip 1) or a layout in which the output circuit cells are arranged parallel to the chip sides of the semiconductor chip 1 without being stepwise shifted, is acceptable as long as high voltage potential interconnects 2 (and reference potential interconnects 3a) each having a shape which will be described below and which characterizes the present embodiment can be arranged.

The reference potential interconnects 3a are formed such that each of the interconnects 3a lies over the low-side transistors 11 in the output circuit cells 16A and is connected to the reference potential pads 5 arranged on both the ends of the plurality of output circuit cells 16A.

The high voltage potential interconnects 2 are formed such that each of the high voltage potential interconnects 2 lies over the high-side transistors 10 in the output circuit cells 16A and is connected to the high voltage power source pads 4 arranged on both the ends of the plurality of output circuit cells 16A. Here, as described above, the plurality of output circuit cells 16A is arranged having a steplike shift in a direction apart from the chip sides with decreasing distance from the center portion to the end portions of the chip sides of the semiconductor chip 1. Therefore, by making use of this layout, the width of each high voltage potential interconnect 2 is expanded from its center portion to its end portions so that portions on which a load current from the pads 8 more concentrates are wide. Thus, interconnect resistances from the center portion of the interconnect 2 to the high voltage power source pads 4 can be made uniform. Therefore, a variation in ESD tolerance is suppressed and a variation in ON resistance between outputs due to different voltage drops is reduced, so that output characteristics can be made uniform.

Moreover, since wires are bonded from a package to the reference potential pads 5 and the high voltage power source pads 4 arranged on both the ends of the plurality of output circuit cells 16A on the semiconductor chip 1, potentials of the reference potential pads 5 and the high voltage power source pads 4 are stable. Therefore, it is possible to reduce the interconnect impedance of each of the reference potential interconnects 3a and the high voltage potential interconnects 2. Moreover, even when large currents are output from respective channels, the reference potential and the high voltage potential of each of the output circuit cells 16A are stable, which makes it possible to obtain the output characteristics and ESD breakdown tolerance which are uniform.

Meanwhile, an input control pad 9 is arranged on one end side in the length direction of the low breakdown control portion 6, and a reference potential pad 5 is arranged on the other end side. Moreover, over the low breakdown voltage control portion 6, a reference potential interconnect 3b is arranged to surround three sides excepting the side where the input control pad 9 is arranged. The reference potential interconnect 3b serves as a shield which prevents an outer noise input from the pads 8 from being transmitted to the low breakdown voltage control portion 6 via the output control cells 16A. Therefore, the signal input from the low breakdown voltage control portion 6 to the pre-drivers 13 is stabilized, which makes the output characteristics uniform. It is to be noted that as the output circuit cells 16A are arranged having a steplike shift in a direction apart from the chip sides with decreasing distance from the center portion to the end portions of the chip sides of the semiconductor chip 1, the low breakdown voltage control portion 6 is likewise formed to have a slope shift in a direction apart from the chip sides with decreasing distance from the center portion to the end portions of the chip sides.

Moreover, since the layout of the output circuit cells 16A can mostly prevent increase in chip area in the right and left directions of the semiconductor chip 1, the bus interconnects 7 having a uniform interconnect length can be used to transmit the control signal from the low breakdown voltage control portion 6 to the pre-drivers 13. Therefore, in the present embodiment, the bus interconnects 7 connecting the pre-drives 13 with the low breakdown voltage control portion 6 have substantially the same length. Therefore, the delay times are made uniform to prevent the output characteristics from being unbalanced due to the difference in delay time between output channels.

Variations

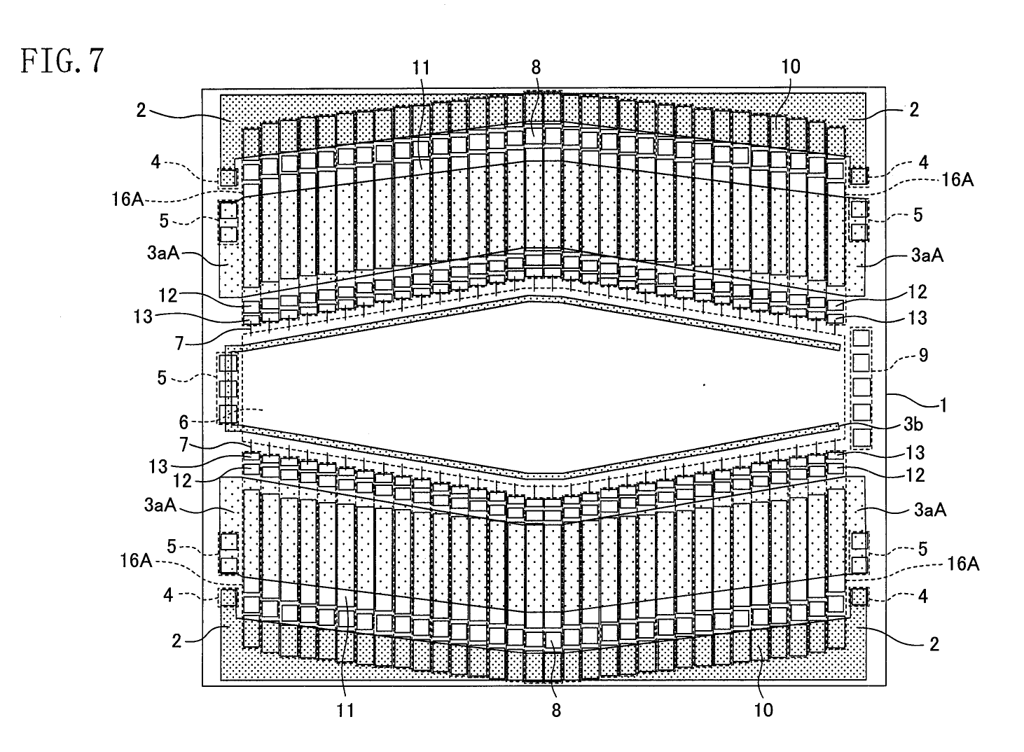

FIG. 7 is a plan view illustrating a layout of a variation of the semiconductor integrated circuit according to Embodiment 1 of the present invention.

As shown in FIG. 7, the variation of the semiconductor integrated circuit according to the present embodiment is characterized by the shape of reference potential interconnects 3aA formed over the low-side transistors 11 in the output circuit cells 16A. Specifically, as the high voltage potential interconnects 2, the width of each reference potential interconnect 3aA is expanded with decreasing distance from the center portion to the end portions of the interconnect 3aA so that portions on which a load current from the pads 8 more concentrates are wide. Thus, an interconnect resistance from the center portion of the interconnect 3aA to the reference potential pads 5 can be made uniform. Therefore, a variation in ESD tolerance is suppressed and a variation in ON resistance between outputs due to different voltage drops is reduced, so that output characteristics can be made uniform.

In FIG. 7, descriptions have been given of the configuration in which the width of each reference potential interconnect 3aA as well as the width of each high voltage potential interconnect 2 are expanded with decreasing distance from the center portion to the end portions thereof. However, a configuration may be acceptable in which the width of each high voltage potential interconnect 2 is constant, and only the width of each reference potential interconnect 3aA is formed to have the above-mentioned shape.

### EMBODIMENT 2

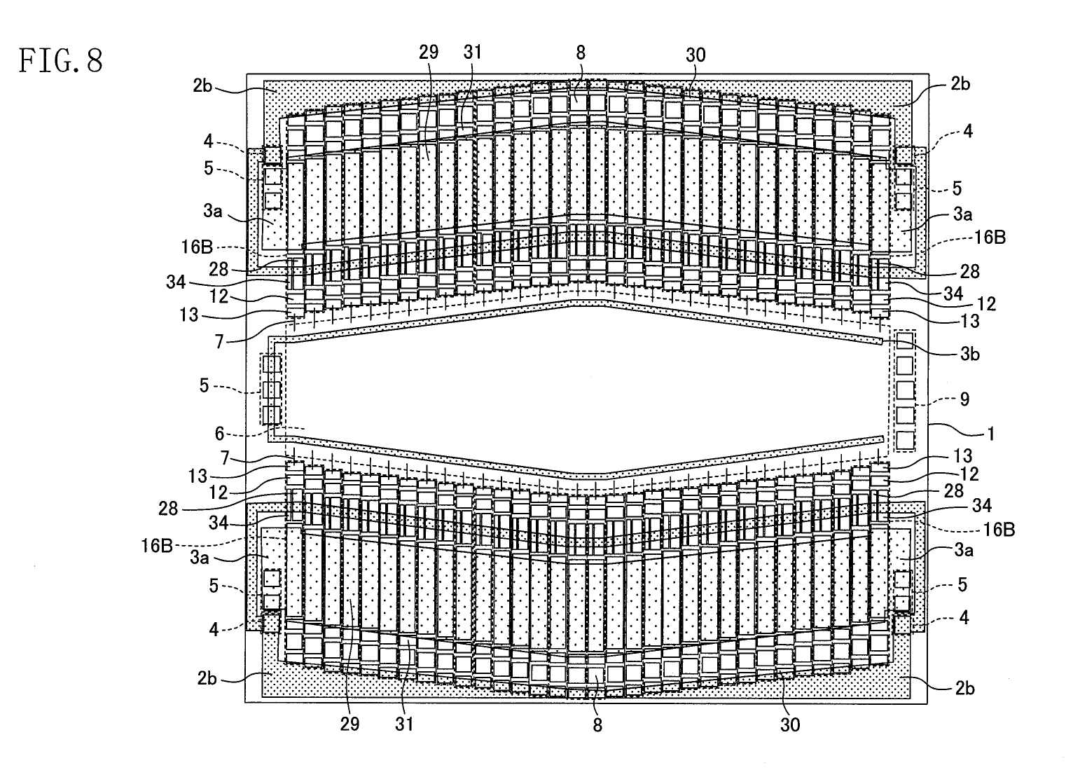

FIG. 8 is a plan view illustrating a layout of a multi-channel semiconductor integrated circuit of Embodiment 2 of the present invention. Specifically, descriptions are given taking a multi-channel semiconductor integrated circuit provided with output circuits 25b each including the IGBT output circuit 46 of FIG. 2 mentioned above as an example.

As shown in FIG. 8, a low breakdown voltage control portion 6 is arranged in the center of a semiconductor chip 1. The low breakdown voltage control portion 6 controls output timing by an input control circuit or the like. Moreover, on the semiconductor chip 1, a plurality of output circuit cells 16B is arranged along chip sides to face each other with the low breakdown voltage control portion 6 interposed therebetween. Each of the plurality of circuit cells 16B has the configuration of the output circuit 25b of FIG. 2. The low breakdown voltage control portion 6 is connected to the output circuit cells 16B via bus interconnects 7. Moreover, high voltage power source pads 4 are arranged on both ends of the plurality of output circuit cells 16B, and reference potential pads 5 are arranged on both the ends of the plurality of output circuit cells 16B.

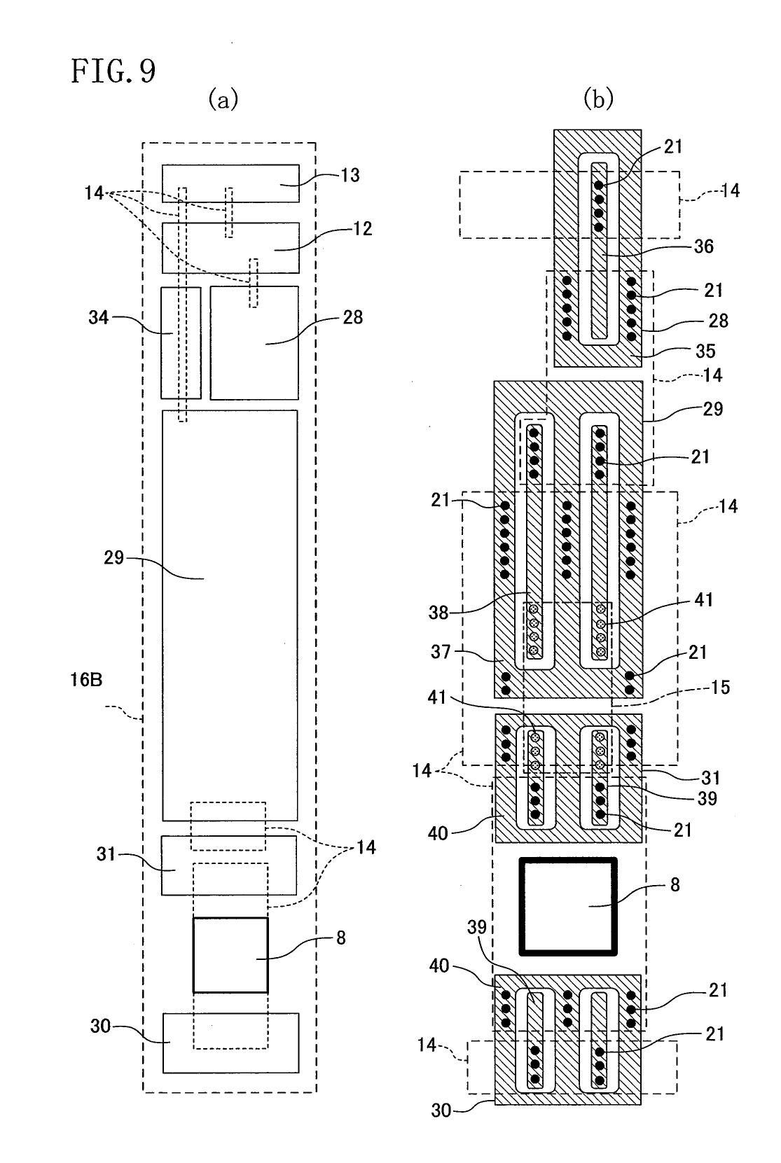

Each output circuit cell 16B is composed of the pad 8, the high-side transistor 28, the low-side transistor 29, a high-side regenerative diode 30, a low-side regenerative diode 31, the level shift circuit 12, and the pre-driver 13 which are arranged in alignment with each other along a straight line, wherein centering on the pad 8, the low-side regenerative diode 31, the low-side transistor 29, the high-side transistor 28, the gate protection circuit 34, the level shift circuit 12, and the pre-driver 13 are sequentially arranged on one side toward the low breakdown voltage control portion 6, and the high-side regenerative diode 30 is arranged on the other side. It is to be noted that a timing control signal from the low breakdown voltage control portion 6 is transmitted to the pre-drivers 13 through the bus interconnects 7. Moreover, components in each output circuit cell 16B are connected by a two-layer interconnect 14 or a one-layer interconnect 15 as shown in FIGS. 9A and 9B. In FIG. 9B, through holes 21, contacts 41, an emitter region 35 of the high-side transistor 28, a corrector region 36 of the high-side transistor 28, an emitter region 37 of the low-side transistor 29, a corrector region 38 of the low-side transistor 29, a cathode region 39 of the low-side regenerative diode 31 and the high-side regenerative diode 30, and an anode region 40 of the low-side regenerative diode 31 and the high-side regenerative diode 30 are shown.

As mentioned above, the high-side regenerative diode 30 and the low-side regenerative diode 31 which serve as ESD protection devices in consideration of improving the ESD tolerance are arranged with the pad 8 interposed therebetween. Thus, the effect of ESD protection can be enhanced. Moreover, each of the level shift circuit 12 and the pre-driver 13 is designed to have a cell width smaller than or equal to that of the low-side transistor 29, where the low-side transistor 29 has the largest cell width, so that a high degree of integration can be realized.

Moreover, the plurality of output circuit cells 16B is arranged having a steplike shift in a direction apart from the chip sides with decreasing distance from a center portion to end portions of the chip sides of the semiconductor chip 1. That is, a layout is performed such that bonding wires (not shown) connecting the pads 8 to inner leads which are not shown are not in contact with each other. Therefore, enhancement of reliability as to assembly can be realized, and the integration degree of the semiconductor integrated circuit can be improved. It is to be noted that this layout of the plurality of output circuit cells 16B is not restrictive. Any layout, such as a layout in which the output circuit cells are stepwise shifted as mentioned above only in the vicinity of the end portions the chip sides of the semiconductor chip 1 (corners of the semiconductor chip 1) or a layout in which the output circuit cells are arranged parallel to the chip sides of the semiconductor chip 1 without being stepwise shifted, is acceptable as long as high voltage potential interconnects 2b (and reference potential interconnects 3a) each having a shape which will be described below and which characterizes the present embodiment can be arranged.

The reference potential interconnects 3a are formed such that each of the interconnects 3a lies over the low-side transistors 29 and the low-side regenerative diodes 31 in the output circuit cells 16B and is connected to the reference potential pads 5 arranged on both the ends of the plurality of output circuit cells 16B.

The high voltage potential interconnects 2b are formed such that each of the high voltage potential interconnects 2b lies over the high-side transistors 28 and the high-side regenerative diodes 30 in the output circuit cells 16B and is connected to the high voltage power source pads 4 arranged on both the ends of the plurality of output circuit cells 16B. Here, as described above, the plurality of output circuit cells 16B is arranged having a steplike shift in a direction apart from the chip sides with decreasing distance from the center portion to the end portions of the chip sides of the semiconductor chip 1. Therefore, by making use of this layout, the width of each high voltage potential interconnect 2b is expanded from its center portion to its end portions so that portions on which a load current from the pads 8 more concentrates are wide. Thus, interconnect resistances from the center portion of the interconnect 2b to the high voltage power source pads 4 can be made uniform. Therefore, a variation in ESD tolerance is suppressed and a variation in ON resistance between outputs due to different voltage drops is reduced, so that output characteristics can be made uniform.

Moreover, since wires are bonded from a package to the reference potential pads 5 and the high voltage power source pads 4 arranged on both the ends of the plurality of output circuit cells 16B on the semiconductor chip 1, potentials of the reference potential pads 5 and the high voltage power source pads 4 are stable. Therefore, it is possible to reduce the interconnect impedance of each of the reference potential interconnects 3a and the high voltage potential interconnects 2b. Moreover, even when large currents are output from respective channels, the reference potential and the high voltage potential of each of the output circuit cells 16B are stable, which makes it possible to obtain the output characteristics and ESD breakdown tolerance which are uniform.

Meanwhile, an input control pad 9 is arranged on one end side in the length direction of the low breakdown control portion 6, and a reference potential pad 5 is arranged on the other end side. Moreover, over the low breakdown voltage control portion 6, a reference potential interconnect 3b is arranged to surround three sides excepting the side where the input control pad 9 is arranged. The reference potential interconnect 3b serves as a shield which prevents an outer noise input from the pads 8 from being transmitted to the low breakdown voltage control portion 6 via the output control cells 16B. Therefore, the signal input from the low breakdown voltage control portion 6 to the pre-drivers 13 is stabilized, which makes the output characteristics uniform. It is to be noted that as the output circuit cells 16B are arranged having a steplike shift in a direction apart from the chip sides with decreasing distance from the center portion to the end portions of the chip sides of the semiconductor chip 1, the low breakdown voltage control portion 6 is likewise formed to have a slope shift in a direction apart from the chip sides with decreasing distance from the center portion to the end portions of the chip sides.

Moreover, since the layout of the output circuit cells 16B can mostly prevent increase in chip area in the right and left directions of the semiconductor chip 1, the bus interconnects 7 having a uniform interconnect length can be used to transmit the control signal from the low breakdown voltage control portion 6 to the pre-drivers 13. Therefore, in the present embodiment, the bus interconnects 7 connecting the pre-drives 13 with the low breakdown voltage control portion 6 have substantially the same length. Therefore, the delay times are made uniform to prevent the output characteristics from being unbalanced due to the difference in delay time between output channels.

Variations

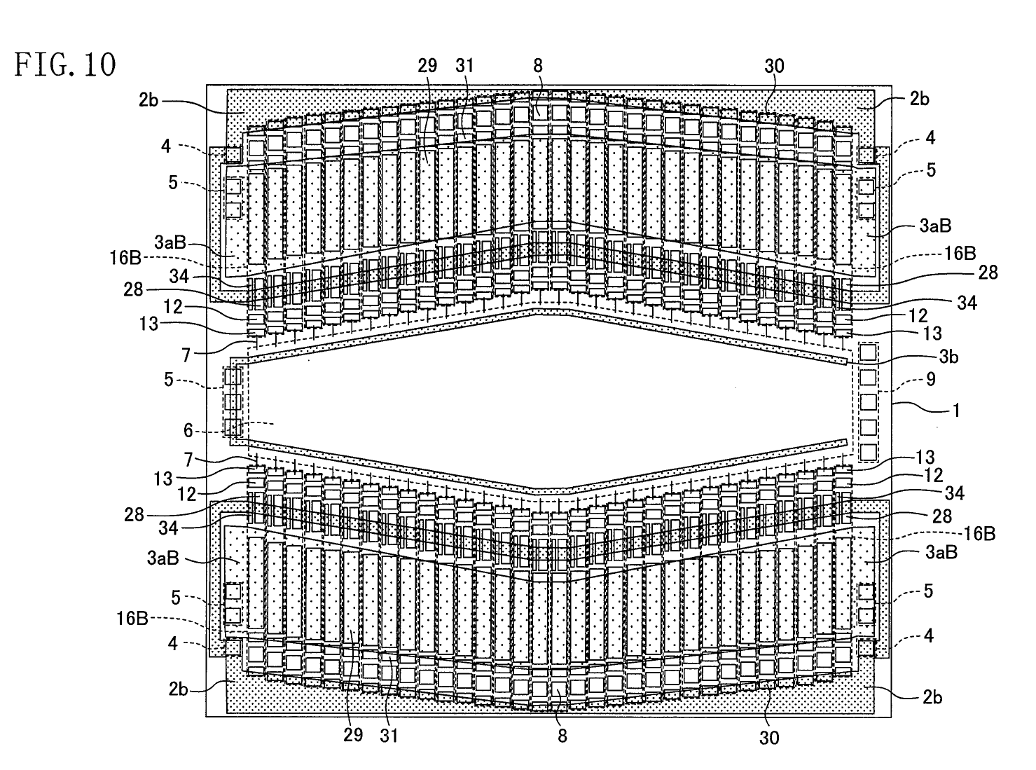

FIG. 10 is a plan view illustrating a layout of a variation of the semiconductor integrated circuit according to Embodiment 2 of the present invention.

As shown in FIG. 10, the variation of the semiconductor integrated circuit according to the present embodiment is characterized by the shape of reference potential interconnects 3aB formed over the low-side transistors 29 and the low-side regenerative diodes 31 in the output circuit cells 16B. Specifically, as the high voltage potential interconnects 2b, the width of each reference potential interconnect 3aB is expanded with decreasing distance from the center portion to the end portions of the interconnect 3aB so that portions on which a load current from the pads 8 more concentrates are wide. Thus, an interconnect resistance from the center portion of the interconnect 3aB to the reference potential pads 5 can be made uniform. Therefore, a variation in ESD tolerance is suppressed and a variation in ON resistance between outputs due to different voltage drops is reduced, so that output characteristics can be made uniform.

In FIG. 10, descriptions have been given of the configuration in which the width of each reference potential interconnect 3aB as well as the width of each high voltage potential interconnect 2b are expanded with decreasing distance from the center portion to the end portions thereof. However, a configuration may be acceptable in which the width of each high voltage potential interconnect 2b is constant, and only the width of each reference potential interconnect 3aB is formed to have the above-mentioned shape.

### EMBODIMENT 3

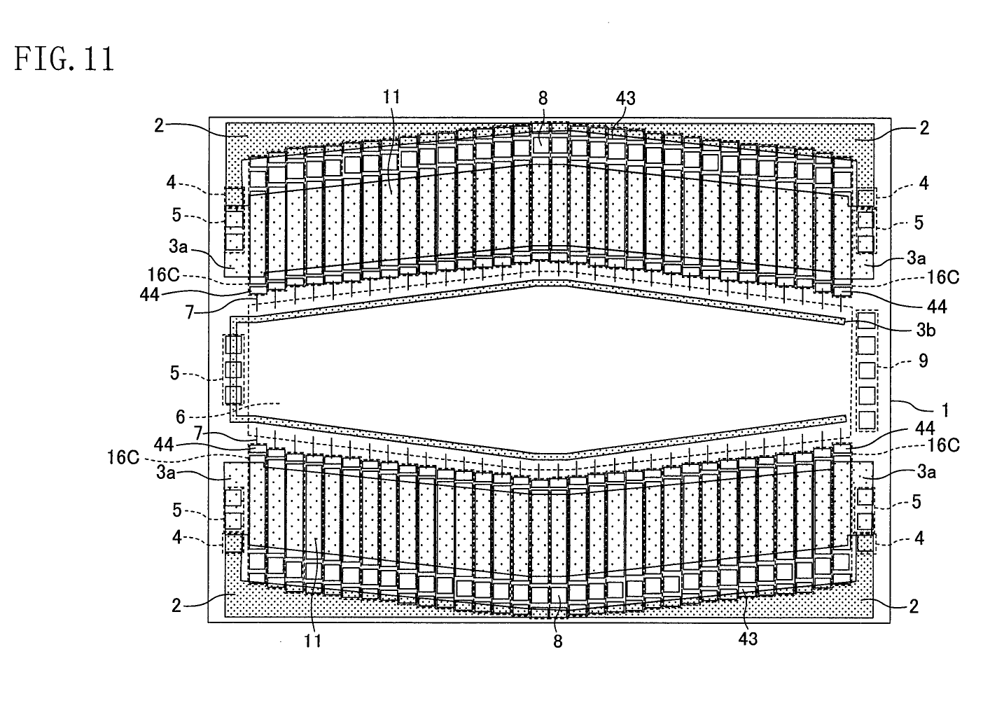

FIG. 11 is a plan view illustrating a layout of a multi-channel semiconductor integrated circuit of Embodiment 3 of the present invention. Specifically, descriptions are given taking a multi-channel semiconductor integrated circuit provided with output circuits 25c each including the high-sideless MOS driver 47 of FIG. 3 mentioned above as an example.

As shown in FIG. 11, a low breakdown voltage control portion 6 is arranged in the center of a semiconductor chip 1. The low breakdown voltage control portion 6 controls output timing by an input control circuit or the like. Moreover, on the semiconductor chip 1, a plurality of output circuit cells 16C is arranged along chip sides to face each other with the low breakdown voltage control portion 6 interposed therebetween. Each of the plurality of circuit cells 16C has the configuration of the output circuit 25c of FIG. 3. The low breakdown voltage control portion 6 is connected to the output circuit cells 16C via bus interconnects 7. Moreover, high voltage power source pads 4 are arranged on both ends of the plurality of output circuit cells 16C, and reference potential pads 5 are arranged on both the ends of the plurality of output circuit cells 16C.

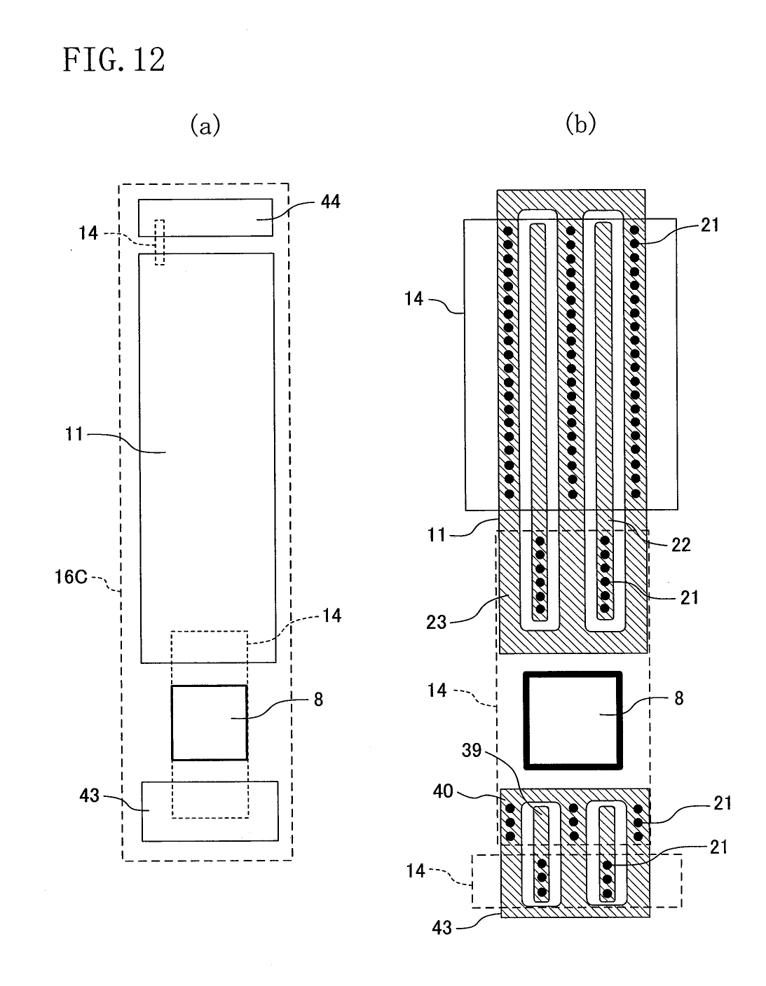

Each output circuit cell 16C is composed of the pad 8, the low-side transistor 11, the pre-driver 44, and the ESD protection device 43 which are arranged in alignment with each other along a straight line, wherein centering on the pad 8, the low-side transistor 11 and the pre-driver 44 are sequentially arranged on one side toward the low breakdown voltage control portion 6, and the ESD protection device 43 is arranged on the other side. It is to be noted that a timing control signal from the low breakdown voltage control portion 6 is transmitted to the pre-drivers 44 through the bus interconnects 7. Moreover, components in each output circuit cell 16C are connected by a two-layer interconnect 14 as shown in FIGS. 12A and 12B. In FIG. 12B, through holes 21, a drain region 22 of the low-side transistor 11, a source region 23 of the low-side transistor 11, a cathode region 39 of the diode, and an anode region 40 of the ESD protection element 43 are shown.

As mentioned above, the ESD protection device 43 and the low-side transistor 11 including the back gate-drain parasitic diode 27 are arranged with the pad 8 interposed therebetween, the back gate-drain parasitic diode 27 also serving as an ESD protection device in consideration of improving the ESD tolerance. Thus, the effect of ESD protection can be enhanced. Moreover, the pre-driver 44 is designed to have a cell width smaller than or equal to that of the low-side transistor 11, where the low-side transistor 11 has the largest cell width, so that a high degree of integration can be realized.

Moreover, the plurality of output circuit cells 16C is arranged having a steplike shift in a direction apart from the chip sides with decreasing distance from a center portion to end portions of the chip sides of the semiconductor chip 1. That is, a layout is performed such that bonding wires (not shown) connecting the pads 8 to inner leads which are not shown are not in contact with each other. Therefore, enhancement of reliability as to assembly can be realized, and the integration degree of the semiconductor integrated circuit can be improved. It is to be noted that this layout of the plurality of output circuit cells 16C is not restrictive. Any layout, such as a layout in which the output circuit cells are stepwise shifted as mentioned above only in the vicinity of the end portions the chip sides of the semiconductor chip 1 (corners of the semiconductor chip 1) or a layout in which the output circuit cells are arranged parallel to the chip sides of the semiconductor chip 1 without being stepwise shifted, is acceptable as long as high voltage potential interconnects 2 (and reference potential interconnects 3a) each having a shape which will be described below and which characterizes the present embodiment can be arranged.

The reference potential interconnects 3a are formed such that each of the interconnects 3a lies over the low-side transistors 11 in the output circuit cells 16C and is connected to the reference potential pads 5 arranged on both the ends of the plurality of output circuit cells 16C.

The high voltage potential interconnects 2 are formed such that each of the high voltage potential interconnects 2 lies over the ESD protection devices 43 in the output circuit cells 16C and is connected to the high voltage power source pads 4 arranged on both the ends of the plurality of output circuit cells 16C. Here, as described above, the plurality of output circuit cells 16C is arranged having a steplike shift in a direction apart from the chip sides with decreasing distance from the center portion to the end portions of the chip sides of the semiconductor chip 1. Therefore, by making use of this layout, the width of each high voltage potential interconnect 2 is expanded from its center portion to its end portions so that portions on which a load current from the pads 8 more concentrates are wide. Thus, interconnect resistances from the center portion of the interconnect 2 to the high voltage power source pads 4 can be made uniform. Therefore, a variation in ESD tolerance is suppressed and a variation in ON resistance between outputs due to different voltage drops is reduced, so that output characteristics can be made uniform.

Moreover, since wires are bonded from a package to the reference potential pads 5 and the high voltage power source pads 4 arranged on both the ends of the plurality of output circuit cells 16C on the semiconductor chip 1, potentials of the reference potential pads 5 and the high voltage power source pads 4 are stable. Therefore, it is possible to reduce the interconnect impedance of each of the reference potential interconnects 3a and the high voltage potential interconnects 2b. Moreover, even when large currents are output from respective channels, the reference potential and the high voltage potential of each of the output circuit cells 16C are stable, which makes it possible to obtain the output characteristics and ESD breakdown tolerance which are uniform.

Meanwhile, an input control pad 9 is arranged on one end side in the length direction of the low breakdown control portion 6, and a reference potential pad 5 is arranged on the other end side. Moreover, over the low breakdown voltage control portion 6, a reference potential interconnect 3b is arranged to surround three sides excepting the side where the input control pad 9 is arranged. The reference potential interconnect 3b serves as a shield which prevents an outer noise input from the pads 8 from being transmitted to the low breakdown voltage control portion 6 via the output control cells 16C. Therefore, the signal input from the low breakdown voltage control portion 6 to the pre-drivers 44 is stabilized, which makes the output characteristics uniform. It is to be noted that as the output circuit cells 16C are arranged having a steplike shift in a direction apart from the chip sides with decreasing distance from the center portion to the end portions of the chip sides of the semiconductor chip 1, the low breakdown voltage control portion 6 is likewise formed to have a slope shift in a direction apart from the chip sides with decreasing distance from the center portion to the end portions of the chip sides.

Moreover, since the layout of the output circuit cells 16C hardly increases the chip area in the right and left directions of the semiconductor chip 1, the bus interconnects 7 having a uniform interconnect length can be used to transmit the control signal from the low breakdown voltage control portion 6 to the pre-drivers 44. Therefore, in the present embodiment, the bus interconnects 7 connecting the pre-drives 44 with the low breakdown voltage control portion 6 have substantially the same length. Therefore, the delay times are made uniform to prevent the output characteristics from being unbalanced due to the difference in delay time between output channels.

Variations

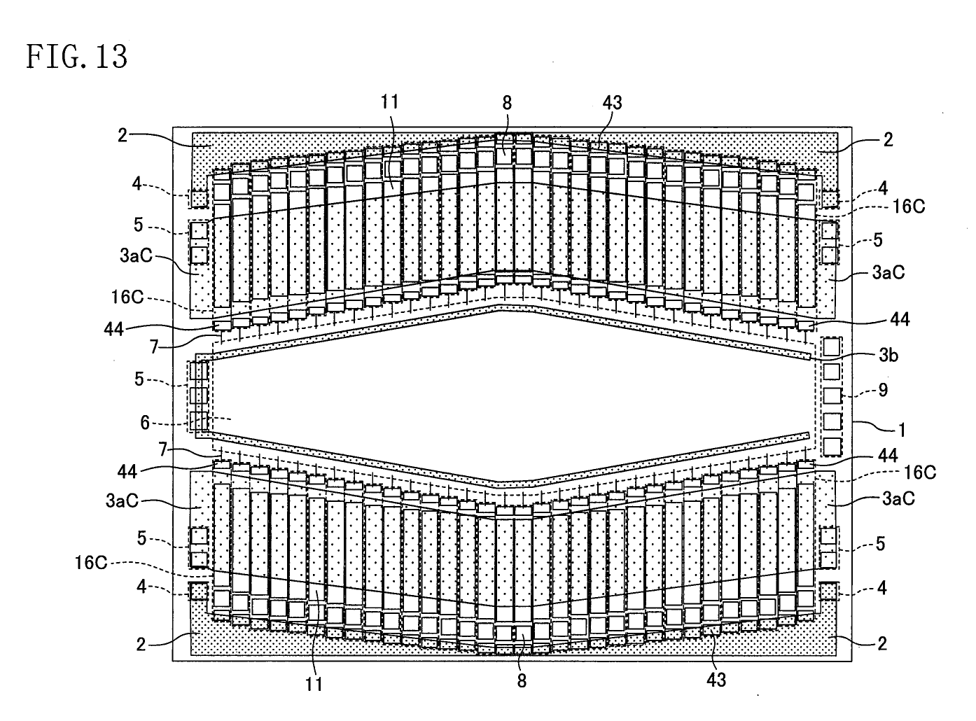

FIG. 13 is a plan view illustrating a layout of a variation of the semiconductor integrated circuit according to Embodiment 3 of the present invention.

As shown in FIG. 13, the variation of the semiconductor integrated circuit according to the present embodiment is characterized by the shape of reference potential interconnects 3aC formed over the low-side transistors 11 in the output circuit cells 16C. Specifically, as the high voltage potential interconnects 2, the width of each reference potential interconnect 3aC is expanded with decreasing distance from the center portion to the end portions of the interconnect 3aC so that portions on which a load current from the pads 8 more concentrates are wide. Thus, an interconnect resistance from the center portion of the interconnect 3aC to the reference potential pads 5 can be made uniform. Therefore, a variation in ESD tolerance is suppressed and a variation in ON resistance between outputs due to different voltage drops is reduced, so that output characteristics can be made uniform.

In FIG. 13, descriptions have been given of the configuration in which the width of each reference potential interconnect 3aC as well as the width of each high voltage potential interconnect 2 are expanded with decreasing distance from the center portion to the end portions thereof. However, a configuration may be acceptable in which the width of each high voltage potential interconnect 2 is constant, and only the width of each reference potential interconnect 3aC is formed to have the above-mentioned shape.

### EMBODIMENT 4

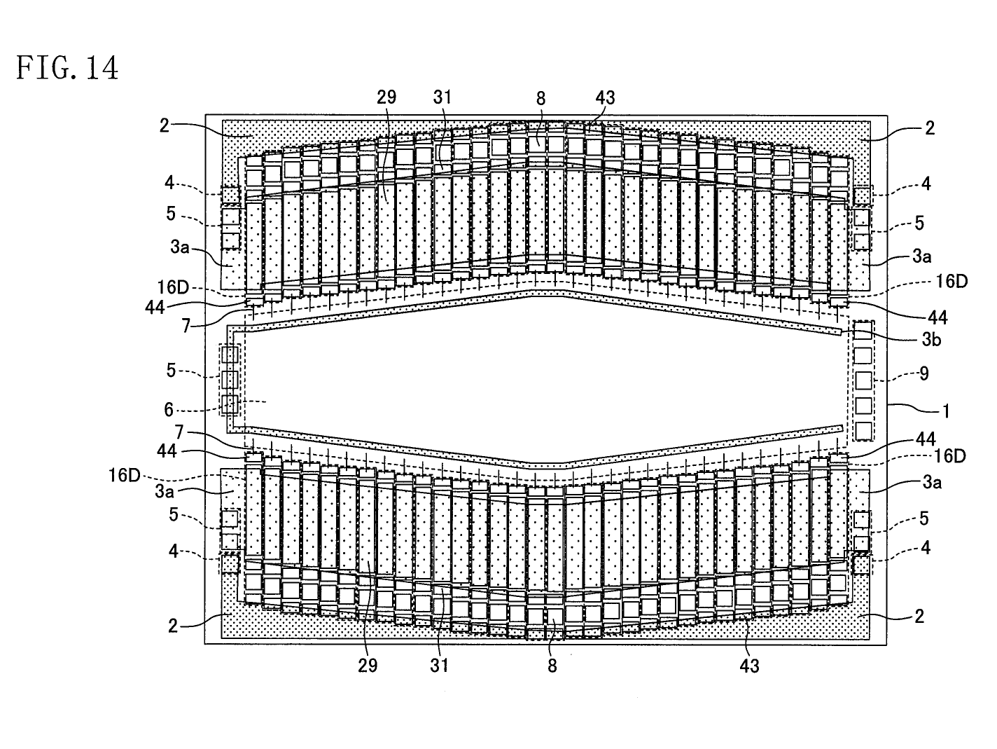

FIG. 14 is a plan view illustrating a layout of a multi-channel semiconductor integrated circuit of Embodiment 4 of the present invention. Specifically, descriptions are given taking a multi-channel semiconductor integrated circuit provided with output circuits 25d each including the high-sideless IGBT output circuit 48 of FIG. 4 mentioned above as an example.

As shown in FIG. 14, a low breakdown voltage control portion 6 is arranged in the center of a semiconductor chip 1. The low breakdown voltage control portion 6 controls output timing by an input control circuit or the like. Moreover, on the semiconductor chip 1, a plurality of output circuit cells 16D is arranged along chip sides to face each other with the low breakdown voltage control portion 6 interposed therebetween. Each of the plurality of circuit cells 16C has the configuration of the output circuit 25d of FIG. 4. The low breakdown voltage control portion 6 is connected to the output circuit cells 16D via bus interconnects 7. Moreover, high voltage power source pads 4 are arranged on both ends of the plurality of output circuit cells 16D, and reference potential pads 5 are arranged on both the ends of the plurality of output circuit cells 16D.

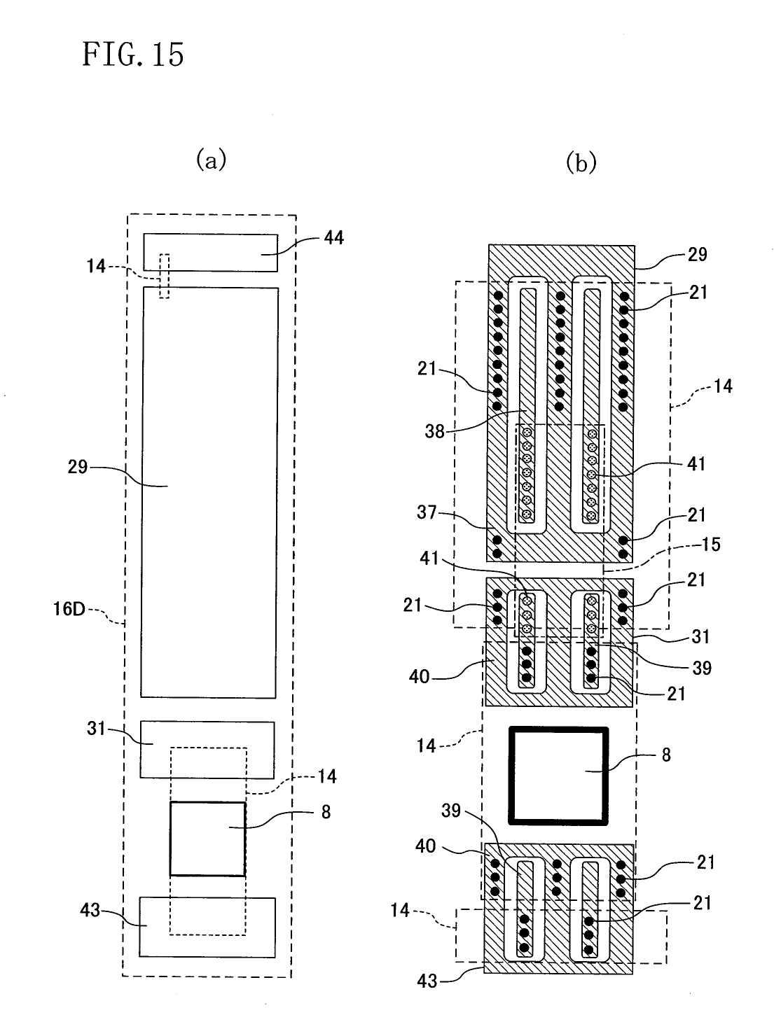

Each output circuit cell 16D is composed of the pad 8, the low-side transistor 29, the low-side regenerative diode 31, the pre-driver 44, and the ESD protection device 43 which are arranged in alignment with each other along a straight line, wherein centering on the pad 8, the low-side regenerative diode 31, the low-side transistor 29, and the pre-driver 44 are sequentially arranged on one side toward the low breakdown voltage control portion 6, and the ESD protection device 43 is arranged on the other side. It is to be noted that a timing control signal from the low breakdown voltage control portion 6 is transmitted to the pre-drivers 44 through the bus interconnects 7. Moreover, components in each output circuit cell 16D are connected by a two-layer interconnect 14 or a one-layer interconnect 15 as shown in FIGS. 15A and 15B. In FIG. 15B, through holes 21, contacts 41, an emitter region 37 of the low-side transistor 29, a corrector region 38 of the low-side transistor 29, a cathode region 39 of the low-side regenerative diode 31 and the ESD protection device 43, and an anode region 40 of the low-side regenerative diode 31 and the ESD protection device 43 are shown.

As mentioned above, the ESD protection device 43 and the low-side regenerative diode 31 are arranged with the pad 8 interposed therebetween, the low-side regenerative diode 31 serving as an ESD protection device in consideration of improving the ESD tolerance. Thus, the effect of ESD protection can be enhanced. Moreover, the pre-driver 44 is designed to have a cell width smaller than or equal to that of the low-side transistor 29, where the low-side transistor 29 has the largest cell width, so that a high degree of integration can be realized.

Moreover, the plurality of output circuit cells 16D is arranged having a steplike shift in a direction apart from the chip sides with decreasing distance from a center portion to end portions of the chip sides of the semiconductor chip 1. That is, a layout is performed such that bonding wires (not shown) connecting the pads 8 to inner leads which are not shown are not in contact with each other. Therefore, enhancement of reliability as to assembly can be realized, and the integration degree of the semiconductor integrated circuit can be improved. It is to be noted that this layout of the plurality of output circuit cells 16D is not restrictive. Any layout, such as a layout in which the output circuit cells are stepwise shifted as mentioned above only in the vicinity of the end portions the chip sides of the semiconductor chip 1 (corners of the semiconductor chip 1) or a layout in which the output circuit cells are arranged parallel to the chip sides of the semiconductor chip 1 without being stepwise shifted, is acceptable as long as high voltage potential interconnects 2 (and reference potential interconnects 3a) each having a shape which will be described below and which characterizes the present embodiment can be arranged.

The reference potential interconnects 3a are formed such that each of the interconnects 3a lies over the low-side transistors 29 in the output circuit cells 16D and is connected to the reference potential pads 5 arranged on both the ends of the plurality of output circuit cells 16D.

The high voltage potential interconnects 2 are formed such that each of the high voltage potential interconnects 2 lies over the ESD protection devices 43 in the output circuit cells 16D and is connected to the high voltage power source pads 4 arranged on both the ends of the plurality of output circuit cells 16D. Here, as described above, the plurality of output circuit cells 16D is arranged having a steplike shift in a direction apart from the chip sides with decreasing distance from the center portion to the end portions of the chip sides of the semiconductor chip 1. Therefore, by making use of this layout, the width of each high voltage potential interconnect 2 is expanded from its center portion to its end portions so that portions on which a load current from the pads 8 more concentrates are wide. Thus, interconnect resistances from the center portion of the interconnect 2 to the high voltage power source pads 4 can be made uniform. Therefore, a variation in ESD tolerance is suppressed and a variation in ON resistance between outputs due to different voltage drops is reduced, so that output characteristics can be made uniform.

Moreover, since wires are bonded from a package to the reference potential pads 5 and the high voltage power source pads 4 arranged on both the ends of the plurality of output circuit cells 16D on the semiconductor chip 1, potentials of the reference potential pads 5 and the high voltage power source pads 4 are stable. Therefore, it is possible to reduce the interconnect impedance of each of the reference potential interconnects 3a and the high voltage potential interconnects 2b. Moreover, even when large currents are output from respective channels, the reference potential and the high voltage potential of each of the output circuit cells 16D are stable, which makes it possible to obtain the output characteristics and ESD breakdown tolerance which are uniform.

Meanwhile, an input control pad 9 is arranged on one end side in the length direction of the low breakdown control portion 6, and a reference potential pad 5 is arranged on the other end side. Moreover, over the low breakdown voltage control portion 6, a reference potential interconnect 3b is arranged to surround three sides excepting the side where the input control pad 9 is arranged. The reference potential interconnect 3b serves as a shield which prevents an outer noise input from the pads 8 from being transmitted to the low breakdown voltage control portion 6 via the output control cells 16D. Therefore, the signal input from the low breakdown voltage control portion 6 to the pre-drivers 44 is stabilized, which makes the output characteristics uniform. It is to be noted that as the output circuit cells 16D are arranged having a steplike shift in a direction apart from the chip sides with decreasing distance from the center portion to the end portions of the chip sides of the semiconductor chip 1, the low breakdown voltage control portion 6 is likewise formed to have a slope shift in a direction apart from the chip sides with decreasing distance from the center portion to the end portions of the chip sides.

Moreover, since the layout of the output circuit cells 16D can mostly prevent increase in chip area in the right and left directions of the semiconductor chip 1, the bus interconnects 7 having a uniform interconnect length can be used to transmit the control signal from the low breakdown voltage control portion 6 to the pre-drivers 44. Therefore, in the present embodiment, the bus interconnects 7 connecting the pre-drives 44 with the low breakdown voltage control portion 6 have substantially the same length. Therefore, the delay times are made uniform to prevent the output characteristics from being unbalanced due to the difference in delay time between output channels.

Variations

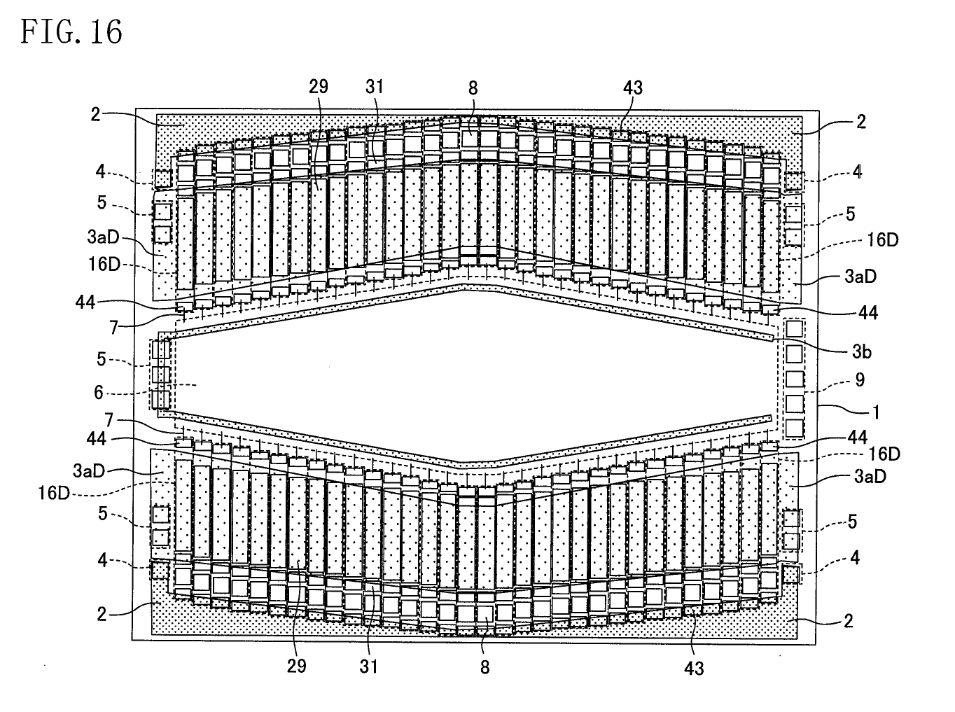

FIG. 16 is a plan view illustrating a layout of a variation of the semiconductor integrated circuit according to Embodiment 4 of the present invention.

As shown in FIG. 16, the variation of the semiconductor integrated circuit according to the present embodiment is characterized by the shape of reference potential interconnects 3aD formed over the low-side transistors 29 in the output circuit cells 16D. Specifically, as the high voltage potential interconnects 2, the width of each reference potential interconnect 3aD is expanded with decreasing distance from the center portion to the end portions of the interconnect 3aD so that portions on which a load current from the pads 8 more concentrates are wide. Thus, an interconnect resistance from the center portion of the interconnect 3aD to the reference potential pads 5 can be made uniform. Therefore, a variation in ESD tolerance is suppressed and a variation in ON resistance between outputs due to different voltage drops is reduced, so that output characteristics can be made uniform.

In FIG. 16, descriptions have been given of the configuration in which the width of each reference potential interconnect 3aD as well as the width of each high voltage potential interconnect 2 are expanded with decreasing distance from the center portion to the end portions thereof. However, a configuration may be acceptable in which the width of each high voltage potential interconnect 2 is constant, and only the width of each reference potential interconnect 3aD is formed to have the above-mentioned shape.

Note that, in the Embodiments above, the term “reference potential” is used to include not only ground potentials but also other potentials. However, the term “reference potential” indicates a potential applied to a substrate of a semiconductor chip and usually means ground potential.

### INDUSTRIAL APPLICABILITY

The present invention is applicable to a multi-channel semiconductor integrated circuit for driving a capacitive load, for example, PDP.

1. A semiconductor integrated circuit including a plurality of circuit cells on a semiconductor chip, the plurality of circuit cells being formed along a first chip side of the semiconductor chip and each of the plurality of circuit cells having a pad, the semiconductor integrated circuit comprising
a high voltage potential interconnect formed over the plurality of circuit cells, wherein the high voltage potential interconnect has a width broader in an end portion than in a center portion in a length direction of the high voltage potential interconnect, and the end portion is provided with an end pad.

2. The semiconductor integrated circuit of claim 1, wherein each of the circuit cells includes:
a high breakdown voltage driver;
a pre-driver for driving the high breakdown voltage driver; and
the pad.

3. The semiconductor integrated circuit of claim 2, wherein
the high breakdown voltage driver includes a high-side transistor and a low-side transistor, and
the pre-driver includes a level shift circuit for driving the high-side transistor.

4. The semiconductor integrated circuit of claim 3, wherein the pre-driver, the pad, the high-side transistor, the level shift circuit, and the low-side transistor are arranged in alignment with each other along a straight line.

5. The semiconductor integrated circuit of claim 4, wherein at least the high-side transistor and the low-side transistor are arranged to face each other with the pad interposed therebetween.

6. The semiconductor integrated circuit of claim 5, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

7. The semiconductor integrated circuit of claim 6, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
first reference potential interconnects arranged over the low-side transistors of the first circuit cell alignment and the second circuit cell alignment, the first reference potential interconnects being electrically connected to the second power source pads,
wherein the high voltage potential interconnects are arranged over the high-side transistors of the first circuit cell alignment and the second circuit cell alignment and are electrically connected to the first power source pads.

8. The semiconductor integrated circuit of claim 7, further comprising a second reference potential interconnect surrounding a region for the control portion arranged in the center of the semiconductor chip.

9. The semiconductor integrated circuit of claim 3, wherein each of the level shift circuit and the pre-driver is designed to have a cell width smaller than or equal to that of the low-side transistor.

10. The semiconductor integrated circuit of claim 2, wherein the high breakdown voltage driver includes:
a high-side transistor;
a high-side regenerative diode;
a low-side transistor; and
a low-side regenerative diode.

11. The semiconductor integrated circuit of claim 10, wherein the pre-driver, the pad, the high-side transistor, the level shift circuit, the high-side regenerative diode, the low-side transistor, and the low-side regenerative diode are arranged in alignment with each other along a straight line.

12. The semiconductor integrated circuit of claim 11, wherein at least the high-side regenerative diode and the low-side regenerative diode are arranged to face each other with the pad interposed therebetween.

13. The semiconductor integrated circuit of claim 12, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

14. The semiconductor integrated circuit of claim 13, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
first reference potential interconnects arranged over the low-side transistors of the first circuit cell alignment and the second circuit cell alignment, the first reference potential interconnects being electrically connected to the second power source pads,
wherein the high voltage potential interconnects are arranged over the high-side regenerative diodes of the first circuit cell alignment and the second circuit cell alignment and are electrically connected to the first power source pads.

15. The semiconductor integrated circuit of claim 14, further comprising a second reference potential interconnect surrounding a region for the control portion arranged in the center of the semiconductor chip.

16. The semiconductor integrated circuit of claim 10, wherein each of the level shift circuit and the pre-driver is designed to have a cell width smaller than or equal to that of the low-side transistor.

17. The semiconductor integrated circuit of claim 2, wherein the high breakdown voltage driver includes an ESD protection device and a low-side transistor.

18. The semiconductor integrated circuit of claim 17, wherein the pre-driver, the pad, the ESD protection device, and the low-side transistor are arranged in alignment with each other along a straight line.

19. The semiconductor integrated circuit of claim 18, wherein at least the ESD protection device and the low-side transistor are arranged to face each other with the pad interposed therebetween.

20. The semiconductor integrated circuit of claim 19, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

21. The semiconductor integrated circuit of claim 20, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
first reference potential interconnects arranged over the low-side transistors of the first circuit cell alignment and the second circuit cell alignment, the first reference potential interconnects being electrically connected to the second power source pads,
wherein the high voltage potential interconnects are arranged over the ESD protection devices of the first circuit cell alignment and the second circuit cell alignment and are electrically connected to the first power source pads.

22. The semiconductor integrated circuit of claim 21, further comprising a second reference potential interconnect surrounding a region for the control portion arranged in the center of the semiconductor chip.

23. The semiconductor integrated circuit of claim 17, wherein the pre-driver is designed to have a cell width smaller than or equal to that of the low-side transistor.

24. The semiconductor integrated circuit of claim 2, wherein the high breakdown voltage driver includes:
an ESD protection device;
a low-side regenerative diode; and
a low-side transistor.

25. The semiconductor integrated circuit of claim 24, wherein the pre-driver, the pad, the ESD protection device, the low-side regenerative diode, and the low-side transistor are arranged in alignment with each other along a straight line.

26. The semiconductor integrated circuit of claim 25, wherein at least the ESD protection device and the low-side regenerative diode are arranged to face each other with the pad interposed therebetween.

27. The semiconductor integrated circuit of claim 26, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

28. The semiconductor integrated circuit of claim 27, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
first reference potential interconnects arranged over the low-side transistors of the first circuit cell alignment and the second circuit cell alignment, the first reference potential interconnects being electrically connected to the second power source pads,
wherein the high voltage potential interconnects are arranged over the ESD protection devices of the first circuit cell alignment and the second circuit cell alignment and are electrically connected to the first power source pads.

29. The semiconductor integrated circuit of claim 28, further comprising a second reference potential interconnect surrounding a region for the control portion arranged in the center of the semiconductor chip.

30. The semiconductor integrated circuit of claim 24, wherein the pre-driver is designed to have a cell width smaller than or equal to that of the low-side transistor.

31. A semiconductor integrated circuit including a plurality of circuit cells on a semiconductor chip, the plurality of circuit cells being formed along a first chip side of the semiconductor chip and each of the plurality of circuit cells having a pad, the semiconductor integrated circuit comprising
a first reference potential interconnect formed over the plurality of circuit cells, wherein the first reference potential interconnect has a width broader in an end portion than in center portion in a length direction of the first reference potential interconnect, and the end portion is provided with an end pad.

32. The semiconductor integrated circuit of claim 31, wherein each of the circuit cells includes:
a high breakdown voltage driver;
a pre-driver for driving the high breakdown voltage driver; and
the pad.

33. The semiconductor integrated circuit of claim 32, wherein
the high breakdown voltage driver includes a high-side transistor and a low-side transistor, and
the pre-driver includes a level shift circuit for driving the high-side transistor.

34. The semiconductor integrated circuit of claim 33, wherein the pre-driver, the pad, the high-side transistor, the level shift circuit, and the low-side transistor are arranged in alignment with each other along a straight line.

35. The semiconductor integrated circuit of claim 34, wherein at least the high-side transistor and the low-side transistor are arranged to face each other with the pad interposed therebetween.

36. The semiconductor integrated circuit of claim 35, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

37. The semiconductor integrated circuit of claim 36, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
high voltage potential interconnects arranged over the high-side transistors of the first circuit cell alignment and the second circuit cell alignment, the high voltage potential interconnects being electrically connected to the first power source pads,
wherein the first reference potential interconnects are arranged over the low-side transistors of the first circuit cell alignment and the second circuit cell alignment and are electrically connected to the second power source pads.

38. The semiconductor integrated circuit of claim 37, further comprising a second reference potential interconnect surrounding a region for the control portion arranged in the center of the semiconductor chip.

39. The semiconductor integrated circuit of claim 33, wherein each of the level shift circuit and the pre-driver is designed to have a cell width smaller than or equal to that of the low-side transistor.

40. The semiconductor integrated circuit of claim 32, wherein the high breakdown voltage driver includes:
a high-side transistor;
a level shift circuit for driving the high-side transistor;
a high-side regenerative diode;
a low-side transistor; and
a low-side regenerative diode.

41. The semiconductor integrated circuit of claim 40, wherein the pre-driver, the pad, the high-side transistor, the level shift circuit, the high-side regenerative diode, the low-side transistor, and the low-side regenerative diode are arranged in alignment with each other along a straight line.

42. The semiconductor integrated circuit of claim 41, wherein at least the high-side regenerative diode and the low-side regenerative diode are arranged to face each other with the pad interposed therebetween.

43. The semiconductor integrated circuit of claim 42, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

44. The semiconductor integrated circuit of claim 43, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
high voltage potential interconnects arranged over the high-side regenerative diodes of the first circuit cell alignment and the second circuit cell alignment, the high voltage potential interconnects being electrically connected to the first power source pads,
wherein the first reference potential interconnects are arranged over the low-side transistors of the first circuit cell alignment and the second circuit cell alignment and are electrically connected to the second power source pads.

45. The semiconductor integrated circuit of claim 44, further comprising a second reference potential interconnect surrounding a region for the control portion arranged in the center of the semiconductor chip.

46. The semiconductor integrated circuit of claim 40, wherein each of the level shift circuit and the pre-driver is designed to have a cell width smaller than or equal to that of the low-side transistor.

47. The semiconductor integrated circuit of claim 32, wherein the high breakdown voltage driver includes:
an ESD protection device; and
a low-side transistor.

48. The semiconductor integrated circuit of claim 47, wherein the pre-driver, the pad, the ESD protection device, and the low-side transistor are arranged in alignment with each other along a straight line.

49. The semiconductor integrated circuit of claim 48, wherein at least the ESD protection device and the low-side transistor are arranged to face each other with the pad interposed therebetween.

50. The semiconductor integrated circuit of claim 49, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

51. The semiconductor integrated circuit of claim 50, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
high voltage potential interconnects arranged over the ESD protection devices of the first circuit cell alignment and the second circuit cell alignment, the high voltage potential interconnects being electrically connected to the first power source pads,
wherein the first reference potential interconnects are arranged over the low-side transistors of the first circuit cell alignment and the second circuit cell alignment and are electrically connected to the second power source pads.

52. The semiconductor integrated circuit of claim 51, further comprising a second reference potential interconnect surrounding a region for the control portion arranged in the center of the semiconductor chip.

53. The semiconductor integrated circuit of claim 47, wherein the pre-driver is designed to have a cell width smaller than or equal to that of the low-side transistor.

54. The semiconductor integrated circuit of claim 32, wherein the high breakdown voltage driver includes:
an ESD protection device;
a low-side regenerative diode; and
a low-side transistor.

55. The semiconductor integrated circuit of claim 54, wherein the pre-driver, the pad, the ESD protection device, the low-side regenerative diode, and the low-side transistor are arranged in alignment with each other along a straight line.

56. The semiconductor integrated circuit of claim 55, wherein at least the ESD protection device and the low-side regenerative diode are arranged to face each other with the pad interposed therebetween.

57. The semiconductor integrated circuit of claim 56, further comprising:
a control portion arranged in the center of the semiconductor chip; and
a second circuit cell alignment of the plurality of circuit cells along a second chip side facing the first chip side of the semiconductor chip, the second circuit cell alignment facing a first circuit cell alignment of the plurality of circuit cells along the first chip side of the semiconductor chip with the control portion interposed therebetween.

58. The semiconductor integrated circuit of claim 57, further comprising:
first power source pads for a high voltage potential, the first power source pads being arranged on both ends of each of the first circuit cell alignment and the second circuit cell alignment;
second power source pads for a reference potential, the second power source pads being arranged on both the ends of each of the first circuit cell alignment and the second circuit cell alignment; and
high voltage potential interconnects arranged over the ESD protection devices of the first circuit cell alignment and the second circuit cell alignment, the high voltage potential interconnects being electrically connected to the first power source pads,
wherein the first reference potential interconnects are arranged over the low-side transistors of the first circuit cell alignment and the second circuit cell alignment and are electrically connected to the second power source pads.

59. The semiconductor integrated circuit of claim 58, further comprising a second reference potential interconnect surrounding a region for the control portion arranged in the center of the semiconductor chip.

60. The semiconductor integrated circuit of claim 54, wherein the pre-driver is designed to have a cell width smaller than or equal to that of the low-side transistor.
